(19) United States
(12) Patent Application Publication
(10) Pub. No.: US 2010/0078308 A1
(43) Pub. Date: Apr. 1, 2010

(54) PROCESS FOR DEPOSITING A COATING ON A BLISK

(75) Inventors: Robert William Bruce, Loveland, OH (US); Jerry Donald Schell, Evendale, OH (US)

Correspondence Address: HARTMAN AND HARTMAN, P.C., 552 EAST 700 NORTH, VALPARAISO, IN, 46383, US

(73) Assignee: General Electric Company, Schenectady, NY (US)

(21) Appl. No.: 12/241,678

(22) Filed: Sep. 30, 2008

(51) Int. Cl. C23C 14/34; C23C 16/06

(52) U.S. Cl. 204/192.1; 427/248.1

(57) ABSTRACT

A process for depositing coatings, and particularly erosion-resistant coatings suitable for protecting surfaces of a gas turbine engine blisk having a disk and integral blades with flowpath surfaces that are susceptible to erosion. The processing involves placing the blisk adjacent a coating material source in an apparatus configured to evaporate the source and generate coating material vapors. The blisk is oriented relative to the coating material source so that the axis of rotation of the blisk is within about forty-five degrees of a linear path that the coating material vapors flow from the coating material source to the blisk, and more erosion-susceptible flowpath surfaces of the blades face the coating material source. The blisk is then rotated about its axis of rotation while the coating material source is evaporated to preferentially deposit the coating material vapors and form a coating on the erosion-susceptible flowpath surfaces of the blades and disk.

### STATEMENT REGARDING FEDERALLY SPONSORED RESEARCH

This invention was made with government support under Contract No. N00421-03-C-0017 awarded by the U.S. Department of the Navy. The Government has certain rights in the invention.

### BACKGROUND OF THE INVENTION

The present invention generally relates to coatings and coating processes, and more particularly to a process for depositing erosion-resistant coatings on blisks and other gas turbine engine components with airflow surfaces that are susceptible to erosion damage.

Gas turbines, including gas turbine engines, generally comprise a compressor, a combustor within which a mixture of fuel and air from the compressor is burned to generate combustion gases, and a turbine driven to rotate by the combustion gases leaving the combustor. Both the compressor and turbine utilize blades with airfoils against which air (compressor) or combustion gases (turbine) are directed during operation of the gas turbine engine, and whose surfaces are therefore subjected to impact and erosion damage from particles entrained in the air ingested by the engine. Turboshaft engines used in helicopters are particularly prone to ingesting significant amounts of particulates when operated under certain conditions, such as in desert environments where sand ingestion is likely.

Though both are attributable to ingested particles, impact damage can be distinguished from erosion damage. Impact damage is primarily caused by high kinetic energy particle impacts, and typically occurs on the leading edge of an airfoil. Traveling at relatively high velocities, particles strike the leading edge or section of the airfoil at a shallow angle to the pressure (concave) surface of the airfoil, such that impact with the leading edge is head-on or nearly so. Because the airfoil is typically formed of a metal alloy that is at least somewhat ductile, particle impacts can deform the leading edge, forming burrs that can disturb and constrain airflow, degrade compressor efficiency, and reduce the fuel efficiency of the engine. Erosion damage is primarily caused by glancing or oblique particle impacts on the pressure side of an airfoil, and tends to be concentrated in an area forward of the trailing edge, and secondarily in an area aft or beyond the leading edge. Such glancing impacts tend to remove material from the pressure surface, especially near the trailing edge. The result is that the airfoil gradually thins and loses its effective surface area due to chord length loss, resulting in a decrease in compressor performance of the engine. Due to their location near the entrance to the engine, compressor blades suffer from both impact and erosion damage along their flowpath surfaces, particularly impact damage along their leading edges and erosion damage on their pressure (concave) surfaces.

Compressors of gas turbine engines of the type used in helicopters are often fabricated as blisks, in which a disk and its blades are manufactured as a single integral part, as opposed to manufacturing the disk and blades separately and then mechanically fastening the blades to the disk. FIG. 1 is representative of a blisk 10 of a type for use in a gas turbine engine. The blisk 10 has a disk 12 (also referred to as a wheel, rotor, hub, etc.) from which blades 14 radially extend. Characteristic of blisks, the blades 14 are fabricated integral with the disk 12, yielding what is also referred to as a bladed disk or an integrally bladed rotor. Each blade 14 has an airfoil portion having oppositely-disposed concave (pressure) and convex (suction) surfaces 16 and 18, oppositely-disposed leading and trailing edges 20 and 22, and a blade tip 24.

The airfoil surfaces of the blisk are typically protected with a coating that may be deposited using various techniques, including physical vapor deposition (PVD), chemical vapor deposition (CVD), and thermal spray processes such as high velocity oxy-fuel (HVOF) deposition. As known in the art, HVOF deposition is a thermal spray process by which particles are entrained in a supersonic stream of hydrogen and oxygen undergoing combustion. The supersonic stream and its entrained particles are directed at a surface, where the softened particles deposit as “splats” to produce a coating having noncolumnar, irregular flattened grains and a degree of inhomogeneity and porosity. PVD processes such as sputtering and electron beam physical vapor deposition (EB-PVD) deposit coatings are microstructurally different from HVOF coatings in terms of being denser and/or having columnar microstructures instead of irregular flattened grains.

The effectiveness of a protective coating on a blisk is particularly important since the entire blisk must be removed from the engine if sufficient erosion or impact damage has occurred to either the blades or disk. Coating materials widely used to protect blisks are generally hard, erosion-resistant materials such as nitrides and carbides. For example, see U.S. Pat. No. 4,904,528 to Gupta et al. (titanium nitride coatings), U.S. Pat. No. 4,839,245 to Sue et al. (zirconium nitride coatings), and U.S. Pat. No. 4,741,975 to Naik et al. (tungsten carbide and tungsten carbide/tungsten coatings). While exhibiting suitable erosion resistance, hard coating materials such as titanium nitride are not as resistant to impact damage. Greater impact resistance has been achieved with relatively thick coatings formed of tungsten carbide and chromium carbide applied by an HVOF deposition process to thicknesses of about 0.003 inch (about 75 micrometers). The required thickness of these coating materials can result in excessively heavy coatings that may negatively affect blade fatigue life (for example, high-cycle fatigue (HCF)), and for that reason the coatings are often applied to only the pressure side of a blade near the blade tip. Furthermore, while HVOF-deposited tungsten carbide and chromium carbide coatings perform well when subjected to relatively round particles found in desert sands, these coatings tend to exhibit higher rates of erosion when subjected to more aggressive particles, such as crushed alumina and crushed quartz, whose shapes tend to be more irregular with sharp corners.

If deposited by a PVD process such as sputtering or EB-PVD, hard erosion-resistant materials such as nitrides and carbides perform better in terms of erosion resistance when subjected to aggressive media such as crushed alumina and crushed quartz. However, uniform coating thicknesses can be difficult to deposit by PVD on the flowpath surfaces of a blisk due to the narrow passages between blades and close proximity of their airfoils. As represented in FIG. 2, conventional practice has been to rotate the blisk 12 around its axis 26, which is oriented parallel to a coating material source 28 so that the blades 14 rotate in a plane parallel to the direction the vapors 30 travel from the source 28 to the blades 14. With this orientation, while nearest the source 28 the blades 14 are coated as the vapors 30 flows radially inward from the blade tips 24 toward the disk 12, simultaneously depositing the coating on the concave (pressure) and convex (suction) surfaces 16 and 18 of the blades. In contrast, individual blades (not part of a blisk, and instead manufactured separately and require assembly to a fan or turbine disk, rotor, or wheel) are typically oriented so that their longitudinal axis is perpendicular to the vapor source, and each blade is individually rotated about its longitudinal axis to produce a uniform coating thickness on its suction and pressure surfaces, while also achieving uniform heating of the blade substrate to promote coating adhesion.

It would be desirable to deposit erosion-resistant coatings of uniform thickness on flowpath surfaces of blisks that are most susceptible to erosion damage.

### BRIEF DESCRIPTION OF THE INVENTION

The present invention provides a process for depositing coatings, and particularly erosion-resistant coatings suitable for protecting surfaces subjected to collisions with particles, including aggressive irregular-shaped particles that tend to inflict erosion damage. The process is particularly well-suited for depositing a coating on a blisk comprising a disk with integral blades that radially extend from the disk and have flowpath surfaces that are more susceptible to erosion from collisions with particles than other flowpath surfaces of the blades and disk.

According to one aspect of the invention, the processing involves placing the blisk adjacent a coating material source in an apparatus configured to evaporate the coating material source and generate coating material vapors. The blisk is oriented relative to the coating material source so that the axis of rotation of the blisk is within about forty-five degrees of a linear path that the coating material vapors flow from the coating material source to the blisk, and the more erosion-susceptible flowpath surfaces of the blades face the coating material source. The blisk is then rotated about its axis of rotation while the coating material source is evaporated to preferentially deposit the coating material vapors and form a coating on the more erosion-susceptible flowpath surfaces of the blades and disk.

A particular advantage of the process is the ability to deposit a uniform coating on those flowpath surfaces of the blades that are more prone to erosion, which are usually concave (pressure) surfaces of the blades. The coating may also be deposited on oppositely-disposed convex (suction) surfaces of the blades, but such coating results from overspray in the sense that erosion is a significant issue to the convex surfaces of blisk blades. The invention has the further advantage of being capable of depositing thinner coatings capable of exhibiting enhanced resistance to erosion damage as compared to coatings deposited by thermal spray processes such as HVOF. As a result, the coatings are well suited for use as protective coatings on blisk blades of gas turbine engines without contributing excessive weight or adversely affecting desirable properties of the blades.

Other objects and advantages of this invention will be better appreciated from the following detailed description.

### BRIEF DESCRIPTION OF THE DRAWINGS

FIG. 1 is a perspective view of an exemplary compressor blisk on which coating processes of this invention can be employed.

FIGS. 2 and 3 schematically represent the orientation of a blisk during coating deposition in accordance with, respectively, the prior art and a preferred embodiment of the present invention.

### DETAILED DESCRIPTION OF THE INVENTION

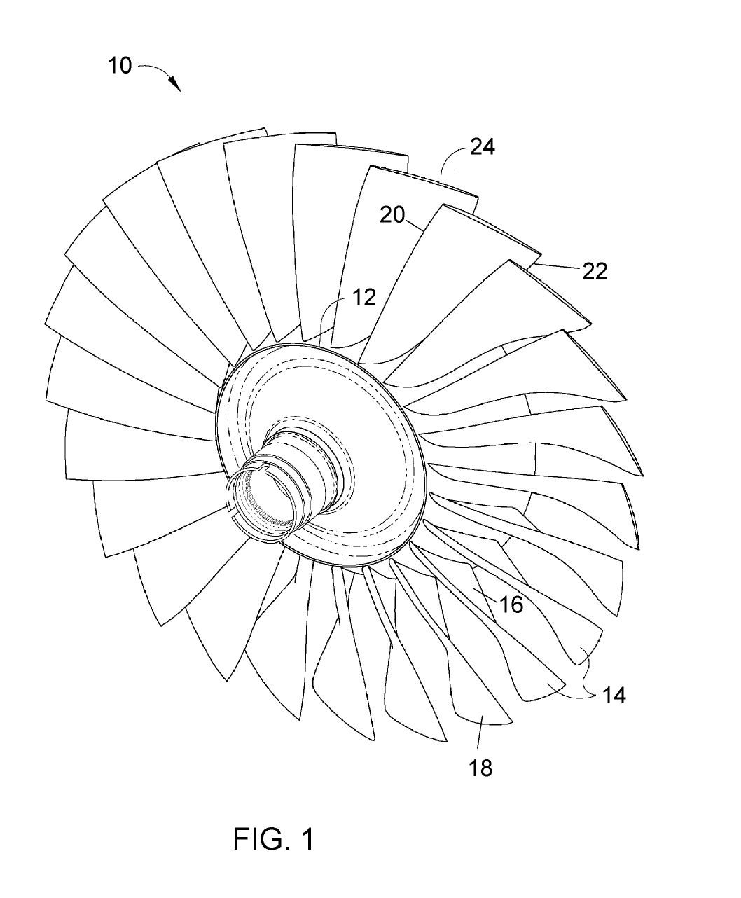

As previously described, FIG. 1 represents a gas turbine engine blisk 10 comprising a disk 12 from which blades 14 radially extend. Each blade 14 has an airfoil portion having oppositely-disposed concave (pressure) and convex (suction) surfaces 16 and 18, oppositely-disposed leading and trailing edges 20 and 22, and a blade tip 24. Characteristic of a blisk, the blades 14 can be fabricated integral with the disk 12, yielding what has also been referred to as a bladed disk or an integrally bladed rotor. The term “integral” is used to denote multiple components that effectively form a single member without any mechanical discontinuity therebetween, whether the components were originally separately formed and then metallurgically joined or originally formed from a single workpiece. The present invention is particularly well suited for fans and compressor blisks on aircraft gas turbine engines, but is applicable to blisks used in other applications. Furthermore, the invention can be useful for other applications and components.

The blades 14 are formed of a material that can be formed to the desired shape, withstand the necessary operating loads, and is compatible with the disk material. Examples of such materials include metal alloys that include, but are not limited to, titanium-, aluminum-, cobalt-, nickel-, and steel-based alloys. Particular examples include steels such as A286 (by weight, about 24% to 27% nickel, 13.5% to 16% chromium, 1% to 1.75% molybdenum, 1.9% to 2.3% titanium, 0.10% to 0.50% vanadium, 0.003% to 0.010% boron, 0.35% maximum aluminum, 0.08% maximum carbon, 2.00% maximum manganese, 1.00% maximum silicon, balance iron) and AM-355 (by weight, about 15% to 16% chromium, 4% to 5% nickel, 2.5% to 3.25% molybdenum, 0.07% to 0.13% nitrogen, 0.50% to 1.25% manganese, 0.50% maximum silicon, 0.040% maximum phosphorus, 0.030% maximum sulfur, balance iron), nickel-based alloys such as IN718 (by weight, about 50-55% nickel, 17-21% chromium, 2.8-3.3% molybdenum, 4.75-5.5% niobium+tantalum, 0-1% cobalt, 0.65-1.15% titanium, 0.2-0.8% aluminum, 0-0.35% manganese, 0-0.3% copper, 0.02-0.08% carbon, 0.006% maximum boron, the balance iron), and titanium-based alloys such as Ti-6Al-4V (by weight, about 6% aluminum, 4% vanadium, balance titanium) and Ti-8Al-1V-1Mo (by weight, about 8% aluminum, 1% vanadium, 1% molybdenum, balance titanium).

When the blisk 10 is installed in the compressor section of a gas turbine engine, the radially outer surfaces of the disk 12 and the concave and convex surfaces 16 and 18 of the blades 14 define what will be termed herein flowpath surfaces, in that they are directly exposed to the air drawn through the engine. The flowpath surfaces of the blisk 10 are subject to impact and erosion damage from particles entrained in the ingested air. In particular, the leading edges 20 of the blades 14 are susceptible to impact damage from particles ingested into the engine, whereas the concave (pressure) surfaces 16 of the blades 14 are prone to erosion damage, particularly forward of the trailing edge 22, aft or beyond the leading edge 20, and near the blade tips 24. To minimize impact and erosion damage, all of the flowpath surfaces of the disk 12 and blades may be provided with a protective coating. According to a particular aspect of the invention, erosion damage is minimized by applying an erosion-resistant ceramic coating to at least the concave surfaces 16 of the blades 14. The ceramic coating may also be applied to the convex (suction) surface 18 of each blade 14, as well as the trailing edges 22 of the blades 14.

The coating may be entirely composed of one or more ceramic compositions, and may be bonded to the blade substrate with a metallic bond coat. For example, in accordance with the teachings of commonly-assigned U.S. patent application Ser. No. 12/201,566 to Bruce et al., the ceramic coating may contain one or more layers of TiAlN, multiple layers of CrN and TiAlN in combination (for example, alternating layers), and one or more layers of TiSiCN, without any metallic interlayers between the ceramic layers. Such ceramic coatings may have a thickness of up to about one hundred micrometers, for example, about twenty-five to about one hundred micrometers. Coating thicknesses exceeding one hundred micrometers are believed to be unnecessary in terms of protection, and undesirable in terms of additional weight. If the ceramic coating is made up of TiAlN, the entire coating thickness can consist of a single layer of TiAlN or multiple layers of TiAlN, and each layer may have a thickness of about twenty-five to about one hundred micrometers. If the ceramic coating is made up of multiple layers of CrN and TiAlN, each layer may have a thickness of about 0.2 to about 1.0 micrometers, for example, about 0.3 to about 0.6 micrometers, to yield a total coating thickness of at least about three micrometers. If the ceramic coating is made up of TiSiCN, the entire coating thickness can consist of a single layer of TiSiCN or multiple layers of TiSiCN, and each layer may have a thickness of about fifteen to about one hundred micrometers. Other coatings, coating compositions, and coating thicknesses are also within the scope of the invention.

If a metallic bond coat is employed, the bond coat may be made up of one or more metal layers, for example, one or more layers of titanium and/or titanium aluminum alloys, including titanium aluminide intermetallics. The bond coat can be limited to being located entirely between the ceramic coating and the substrate it protects for the purpose of promoting adhesion of the ceramic coating to the substrate.

Coatings of this invention are preferably deposited by a physical vapor deposition (PVD) technique, and therefore will generally have a columnar and/or dense microstructure, as opposed to the noncolumnar, irregular, and porous microstructure that would result if the coating were deposited by a thermal spray process such as HVOF. Particularly suitable PVD processes include EB-PVD, cathodic arc PVD, and sputtering, with sputtering believed to be preferred. Suitable sputtering techniques include but are not limited to direct current diode sputtering, radio frequency sputtering, ion beam sputtering, reactive sputtering, magnetron sputtering, plasma-enhanced magnetron sputtering, and steered arc sputtering. Cathodic arc PVD and plasma-enhanced magnetron sputtering are particularly preferred for producing coatings due to their high coating rates. Depending on the coating composition to be deposited, deposition can be carried out in an atmosphere containing a source of carbon (for example, methane), a source of nitrogen (for example, nitrogen gas), or a source of silicon and carbon (for example, trimethylsilane, (CH₃)₃SiH) to form carbide, silicon, and/or nitride constituents of the deposited coating. The metallic bond coat and any other metallic layers are preferably deposited by performing the coating process in an inert atmosphere, for example, argon.

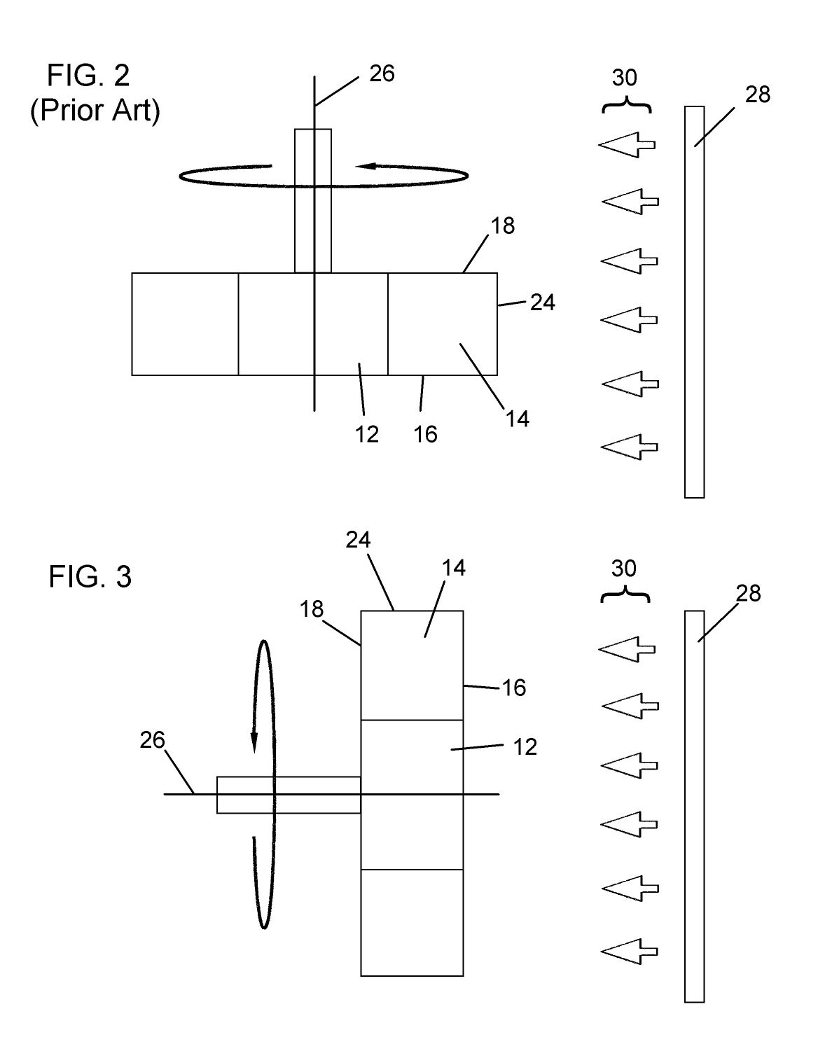

As previously noted, considerable difficulties can be encountered when using PVD processes to deposit coatings (including the erosion-resistant coatings noted above) of uniform thicknesses on flowpath surfaces of blisks. According to a particular aspect of the invention, such prior difficulties can be overcome by appropriately orienting a blisk in the manner represented in FIG. 3. Contrary to the conventional practice represented in FIG. 2, the coating technique of this invention involves rotating the blisk 12 around its axis 26, but with its axis 26 oriented roughly perpendicular to a coating material source 28 so that the blades 14 rotate in a plane perpendicular to the direction the vapors 30 travel to the blades 14. With this orientation, the concave (pressure) surfaces 16 of the blisk blades 14 are continuously nearest the coating material (vapor) source 28, and are therefore preferentially coated as the vapors 30 flow to the blades 14 and then through the narrow passages between the blades 14. Axially vapor flow from the source 28 to the blisk 10 can be promoted by establishing appropriate gas flow patterns and rates within the coating chamber, as is commonly employed in PVD processes, so that the vapors 30 are transported to the blisk 10 and primarily impinge the concave surfaces 16. In this manner, deposition on the concave surfaces 16 will tend to be continuous and uniform, essentially coating the entire concave surface 16. With the orientation shown in FIG. 3, coating material will also tend to deposit on the trailing edges 22 of the blades 14 and the outer radially surfaces of the disk 12. In contrast, coating deposition on the convex (suction) surfaces 18 of the blades 14 will occur farther downstream in the vapor path and primarily due to overspray. However, because the convex surfaces 18 of the blades 14 are significantly less prone to erosion than the concave surfaces 16, the lack of coating on the convex surfaces 18 is believed to be of minimal consequence to the erosion lives of the blades 14 and the blisk 10 as a whole.

For purposes of this invention, a uniform coating thickness is generally intended to denote a coating thickness that does not vary by more than about 50 percent over at least 50 percent of the concave surface 16 of a blade 14. A coating thickness that does not vary by more than about 80 percent over substantially the entire concave surface 16 of a blade 12 is believed to be very desirable though not necessary to benefit from this invention. Excluded from this computation are the leading and trailing edges 20 and 22, the blade tips 24, and the intersections of the blades 14 and disk 12, which will tend to exhibit greater variations of coating thickness due to their more complex geometries.

The orientation and rotation of the blisk 10 can be controlled by individually mounting and rotating one or more blisks 10 in a coating chamber, or mounting multiple blisks 10 on a planetary unit that controls the orientation, rotation and transverse movement of the blisks 10 relative to the surface of the coating material source 28. Planetary units capable of such control are known in the art and therefore will not be discussed in any detail here. While the axis 26 of the blisk 10 is shown in FIG. 3 as being parallel to the path that the vapors 30 travel from the coating material source 28, it is foreseeable that the axis 26 could be oriented up to ±60 degrees from the vapor path (corresponding to about 30 to about 90 degrees to the surface of the coating material source 28). A suitable narrower range for this orientation is up to about ±45 degrees from the vapor path (corresponding to about 45 to about 90 degrees to the surface of the source 28. Oscillations and/or incremental movements of the blisk 10 within these angular ranges relative to the source 28 are also foreseeable. The orientation of the blisk 20 presumes that the vapor path is roughly perpendicular to the surface of the coating material source 28 facing the blisk 10, and follows a straight-line trajectory that originates at the source 28 and travels directly to the blisk 10.

Suitable rotational speeds for the blisk 10 can also typically be ascertained without undue experimentation. Generally, rotational speeds of up to about 10 rpm are believed to be effective, with a narrower suitable range believed to be about 2 to about 7 rpm. Oscillations and/or incremental movements of the blisk 10 may also be incorporated into the rotational movement of the blisk 10.

Distances between the source 28 and the concave surfaces 16 of the blisk 10 will generally be in a range of about 5 to about 20 centimeters. Suitable distances within and outside this range can typically be ascertained without undue experimentation. Generally, distances of about 5 to about 10 centimeters are believed to be particularly suitable.

Other parameters of the coating process required to obtain optimal results will depend on the particular PVD process employed, the particular coating materials being deposited, the particular materials of the disk 12 and blades 14, etc. For example, the coating atmosphere, gas flow rates, and temperature within the coating chamber, the duration of the coating process, the size of the target (coating material source 28), the voltage, size, composition and type of any cathode used (in cathodic arc PVD process), the power, amperage and type of any plasma generator used (in a cathodic arc PVD process), etc., will depend on the particular PVD process employed and the coating materials being deposited. Surface preparation of the blisk 10, including peening, degreasing, heat tinting, grit blasting, back sputtering, etc., often used prior to coating deposition processes to attain desirable surface conditions can also be performed prior to the coating process of this invention.

While the invention has been described in terms of specific embodiments, it is apparent that other forms could be adopted by one skilled in the art. Therefore, the scope of the invention is to be limited only by the following claims.

1. A process of depositing a coating on a blisk comprising a disk with integral blades that radially extend from the disk relative to an axis of rotation of the disk, the blades and disk having flowpath surfaces comprising first flowpath surfaces that are more susceptible to erosion from collisions with particles than other flowpath surfaces of the blades and disk, the processing comprising:
placing the blisk adjacent a coating material source in an apparatus configured to evaporate the coating material source and generate coating material vapors;
orienting the blisk relative to the coating material source so that the axis of rotation of the blisk is within about forty-five degrees a linear path that the coating material vapors flow from the coating material source to the blisk, and the first flowpath surfaces of the blades face the coating material source; and
rotating the blisk about the axis of rotation thereof and evaporating the coating material source to preferentially deposit the coating material vapors and form a coating on the first flowpath surfaces.

2. The process according to claim 1, wherein the coating is an erosion-resistant ceramic coating.

3. The process according to claim 1, wherein the coating material source is evaporated by a physical vapor deposition process and the coating has a columnar and/or dense microstructure.

4. The process according to claim 3, wherein the physical vapor deposition process is sputtering and the coating has a dense microstructure.

5. The process according to claim 3, wherein the physical vapor deposition process is electron beam physical vapor deposition and the coating has a columnar microstructure.

6. The process according to claim 1, wherein the first flowpath surfaces of the blades are concave flowpath surfaces and are oppositely-disposed from convex flowpath surfaces of the blades, and the coating is preferentially deposited the concave flowpath surfaces.

7. The process according to claim 6, wherein the coating entirely and uniformly covers the concave flowpath surfaces of the blades and does not entirely and uniformly cover the convex flowpath surfaces of the blades.

8. The process according to claim 1, wherein the coating is deposited to a total coating thickness of up to about 100 micrometers and has a composition chosen from the group consisting of TiAlN, CrN and TiSiCN.

9. The process according to claim 8, wherein the coating consists of TiAlN.

10. The process according to claim 8, wherein the coating consists of multiple layers of CrN and TiAlN.

11. The process according to claim 8, wherein the coating consists of TiSiCN.

12. A process of depositing an erosion-resistant ceramic coating on a blisk of a gas turbine engine, the blisk comprising a disk with integral blades that radially extend from the disk relative to an axis of rotation of the blisk, the blades and disk having flowpath surfaces, the flowpath surfaces of the blades comprising convex flowpath surfaces and oppositely-disposed concave flowpath surfaces that are more susceptible to erosion from collisions with particles than the convex flowpath surfaces during operation of the blisk within the gas turbine engine, the processing comprising:
placing the blisk adjacent a coating material source in a physical vapor deposition apparatus configured to evaporate the coating material source and generate coating material vapors;
orienting the blisk relative to the coating material source so that the axis of rotation of the blisk is approximately parallel to a linear path that the coating material vapors flow from the coating material source to the blisk, and the concave flowpath surfaces of the blades face the coating material source; and
rotating the blisk about the axis of rotation thereof and evaporating the coating material source to preferentially deposit the coating material vapors and form an erosion-resistant ceramic coating on the concave flowpath surfaces of the blades.

13. The process according to claim 12, wherein the physical vapor deposition apparatus performs sputtering deposition and the erosion-resistant ceramic coating has a dense microstructure.

14. The process according to claim 12, wherein the physical vapor deposition apparatus performs electron beam physical vapor deposition and the coating has a columnar microstructure.

15. The process according to claim 12, wherein the evaporation of the coating material source and deposition of the coating material vapors is by a cathodic arc PVD process or a plasma-enhanced magnetron sputtering process.

16. The process according to claim 12, wherein the erosion-resistant ceramic coating entirely and uniformly covers the concave flowpath surfaces of the blades and does not entirely and uniformly cover the convex flowpath surfaces of the blades.

17. The process according to claim 12, wherein the erosion-resistant ceramic coating is deposited to a total coating thickness of up to about 100 micrometers and has a composition chosen from the group consisting of TiAlN, CrN and TiSiCN.

18. The process according to claim 17, wherein the erosion-resistant ceramic coating consists of TiAlN.

19. The process according to claim 17, wherein the erosion-resistant ceramic coating consists of multiple layers of CrN and TiAlN.

20. The process according to claim 17, wherein the erosion-resistant ceramic coating consists of TiSiCN.
